(19) United States
(12) Patent Application Publication
(10) Pub. No.: US 2008/0066859 A1
(43) Pub. Date: Mar. 20, 2008

(54) Plasma processing apparatus capable of adjusting pressure within processing chamber

(76) Inventors: Michiaki Kobayashi, Kudamatsu (JP); Tsutomu Nakamura, Hikari (JP); Akitaka Makino, Hikari (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/512,124

(22) Filed: Aug. 30, 2006

(51) Int. Cl. H01L 21/306

(52) U.S. Cl. 156/345.1

(57) ABSTRACT

A vacuum pump exhausts gas within the processing chamber from a lower portion of a sample so as to reduce pressure within a processing chamber. The vacuum pump includes a rotary vane and a fixed vane which are arranged within a case of the vacuum pump and have a plurality of impeller blades in a coaxial manner; an exhausting port for exhausting the gas exhausted from the rotary vane outside the case; and a conducting port arranged along a lower direction of the rotary vane, into which inert gas is conducted, which are provided on a circumference thereof. An MFC (flow rate adjusting device) is arranged between a gas storage unit of the inert gas and the conducting port, for adjusting an amount of the inert gas.

### BACKGROUND OF THE INVENTION

The present invention generally relates to a plasma processing apparatus for processing a sample by employing plasma in a processing chamber within a vacuum vessel. More specifically, the present invention is directed to a plasma processing apparatus capable of adjusting pressure within the pressing chamber inside the vacuum vessel by adjusting exhausting of gas within the processing chamber by a vacuum pump.

In the above-described plasma apparatus, very recently, more uniform plasma is strongly required to be formed in higher density in order to realize high precision process operations in very fine manners. Then, in order that such high-density plasma is formed under stable condition, pressure of processing chambers provided within vacuum vessels must be more stably realized in higher vacuum degrees (namely, lower pressure values).

In such conventional plasma processing apparatus, the processing chambers arranged inside the vacuum vessels are coupled to exhausting apparatus such as vacuum pumps, while these exhausting apparatus are employed so as to exhaust gas and plasma present within these processing chambers, and also to exhaust particles such as produced matters which are produced in connection with the process operations executed in the processing chambers. In addition, while such apparatus for adjusting amounts of exhausting gas per unit time are arranged on exhausting passages which are communicated from the processing chambers toward entrances of the vacuum pumps, internal pressure of these processing chambers in which samples like substrates (for example, semiconductor wafers to be processed) are arranged, or plasma is produced is adjusted by adjusting exhausting amounts of gas and particles present within the processing chambers by operating the adjusting apparatus.

Conventionally, in these processing apparatus, such means for adjusting resistances of gas flows and easily flowing degrees (conductances) of these gas flows have been arranged between exhausting ports located under the processing chambers within the vacuum vessels and entrances of the vacuum pumps so as to adjust amounts of gas exhausted from the vacuum vessels, so that internal pressure of these vacuum vessels is adjusted. The gas flows through passages which communicate the exhausting ports with the entrances of the vacuum pumps. As such means capable of adjusting the resistances of these gas flows and the easily flowing degrees, either one valve or plural valves may be used which change dimensions and areas as to openings of the passages, the entrances, or the exhausting ports. Since such valves are rotated, or moved along a direction for accrossing an axis of a passage, the dimensions and the areas of the openings may be adjusted.

The above-described conventional technical ideas have been disclosed in, for instance, JP-A-2005-101598. This conventional technical idea is disclosed as follows: That is, while a plurality of plate-shaped rotatable valves are provided between an opening having a substantially circular shape and a vacuum pump within a processing chamber, an area of a passage through which gas can pass is adjusted in a variable manner by rotating these valves. The opening is arranged just under a sample base used to mount thereon a wafer corresponding to the sample, and through which the gas within the processing chamber is exhausted. The vacuum pump is used so as to exhaust the gas.

Also, as another conventional technical idea, an exhausting amount of gas per unit time from a processing chamber is adjusted by a vacuum pump itself which is connected to a vacuum vessel. Such a conventional technical idea is disclosed in, for example, JP-A-2005-140079. This conventional technical idea is related to such a vacuum pump having an entrance communicated to a processing chamber within a vacuum vessel, more specifically, such a turbo-molecular pump capable of reducing pressure to realize high degree vacuum status. A portion of exhaust gas from an exit unit of a compressing unit is returned from a tip side of moving vane to the compressing unit, while an amount of this partial exhaust gas is adjusted, so that an essential exhausting amount of gas within the processing chamber is adjusted. The compressing unit is equipped with rotary vanes and fixed vanes which are arranged in stacked to be mutually overlapped with each other on the same rotation axis.

### SUMMARY OF THE INVENTION

However, since the above-described conventional technical ideas do not sufficiently consider the below-mentioned points, the following problems may occur.

That is, in the conventional technical idea described in JP-A-2005-101598, if the internal space of the processing chamber is brought into a higher-degree vacuum status, then the plate-shaped valve must be set to a large open degree (otherwise, large opening area). If such a large open degree is set, then precision in pressure adjustments is lowered. In other words, in order to realize such a large open degree, the respective valves are rotated, so that angles of the respective valves along the axial direction of the passage are decreased (namely, planes of valves are approximated parallel to axis of passage). Under this condition, pressure within the processing chamber becomes small, and changes in the gas exhausting amounts are small with respect to changes in the angles of the respective valves. As a result, a so-called “control characteristic” of these valves is lowered, and thus, there is such a problem that a high vacuum degree cannot be realized in high precision under stable condition.

On the other hand, JP-A-2005-140079 also describes the following technical idea: That is, in the vacuum pump equipped with the turbo-unit, the passage for returning a portion of the exhaust gas exhausted from the turbo-unit is provided; and since the exhaust gas is returned, the effective exhausting amount is changed. In the turbo-unit, while the exhaust gas is compressed by the rotary vanes and the fixed vanes fixed to the case, the compressed exhaust gas is exhausted. The rotary vanes are made of a plurality of impeller blades around the rotation axis in the radial form. However, this conventional technical idea described in JP-A-2005-140079 never considers the below-mentioned problem: That is, the particles of the produced matters having the strong adhesive characteristics may be adhered to the vacuum pump, and inside the vacuum pump, for example, may be penetrated into the processing chamber, while these particles are present in the gas of the compressing unit. These particles may become contaminating materials within the processing chamber, so that the processing yield of the sample is lowered and the processing efficiency is lowered.

Moreover, in the construction of this conventional technical idea, there is such a risk that constructions (compositions) of gases located on the intake side and the exhausting side of the vacuum pump are changed, and if such gases are returned to the intake (entrance) side of the vacuum pump, then the constructions of the gasses contained in the processing chamber are changed.

An object of the present invention is to provide a plasma processing apparatus capable of realizing a pressure control operation chamber under stable condition.

Another object of the present invention is to provide a plasma processing apparatus capable of performing a processing operation of a sample in high precision as well as in a superior processing yield.

The above-described objects of the present invention may be achieved by such a plasma processing apparatus for processing a sample by employing plasma produced in a processing chamber, including: a processing chamber in which plasma is formed while process gas is supplied to an inner portion thereof; a sample base in which a sample to be processed is mounted on an upper surface of the sample base; a vacuum pump for exhausting gas within the processing chamber from a lower portion of the sample so as to reduce pressure within the processing chamber, the vacuum pump being equipped with a compressing unit having a rotary vane and a fixed vane arranged within a case of the vacuum pump, and an exhausting port for exhausting the gas exhausted from the processing chamber outside the case of the vacuum pump; and the rotary vane and the fixed vane having a plurality of impeller blades arranged in a coaxial manner; and a conducting port arranged between a rotary vane arranged at the uppermost position of the compressing unit and a fixed vane located under the rotary vane, into which inert gas is conducted; and a flow rate adjusting device arranged between a gas storage unit of the inert gas and the conducting port, for adjusting an amount of the inert gas.

Also, the above-explained objects of the present invention may be achieved by such a plasma processing apparatus for processing a sample by employing plasma produced in a processing chamber, including: a processing chamber in which plasma is formed while process gas is supplied to an inner portion thereof; a sample base in which a sample to be processed is mounted on an upper surface of the sample base; and a vacuum pump equipped with a compressing unit, an exhausting port, a conducting port, a gas returning port, and a flow rate adjusting device, which exhausts gas within a processing chamber from a lower portion of the sample so as to reduce pressure; the compressing unit being constituted by both a rotary vane and a fixed vane which are made of a plurality of impeller blades in a coaxial manner arranged within a case of the vacuum pump under the processing chamber; the exhausting port exhausting the gas exhausted from the compressing unit outside the case; the conducting port being arranged on an outer circumference of the compressing unit between the rotary vane and the fixed vane located under the rotary vane, into which inert gas is conducted; the returning port being arranged on the exhaust side of the compressing unit, which supplies the exhausted gas to the conducting port; and also, the flow rate adjusting device being arranged on a passage for the gas between the gas returning port and the conducting port, which adjusts a flow rate of the gas.

Furthermore, the above-described objects of the present invention may be achieved by that the vacuum pump includes: a turbo-unit having both the rotary vane and the fixed vane, which are arranged in an alternate manner, or an upper/lower direction; and the gas within the processing chamber is directly conducted into an entrance vane from an opening which is communicated to the vacuum vessel, the entrance vane is arranged at an entrance of the turbo-unit and owns the shape of the rotary vane.

Furthermore, the above-described objects of the present invention may be achieved by that the vacuum pump is arranged under the vacuum vessel; and the vacuum pump is directly coupled to an entrance vane having the shape of the rotary vane, which is detachably arranged on an upper entrance portion of a turbo-unit which is mounted under an opening communicated to the processing chamber and is arranged by alternately overlapping the rotary vane with the fixed vane; and the entrance vane is heated by a heating unit in order to avoid that contaminating materials are adhered to the entrance vane.

Moreover, the above-described objects of the present invention may be achieved by that the gas derived from either the gas conducting port or the gas returning port is supplied between the rotary vane of the first stage and the fixed vane of the next stage.

Other objects, features and advantages of the invention will become apparent from the following description of the embodiments of the invention taken in conjunction with the accompanying drawings.

### BRIEF DESCRIPTION OF THE DRAWINGS

FIG. 1A and FIG. 1B are diagrams for schematically showing constructions of a plasma processing apparatus according to an embodiment of the present invention;

FIG. 2 is a sectional view for schematically representing a construction of a processing unit of the embodiment shown in FIG. 1A and FIG. 1B;

FIG. 3 is a longitudinal sectional view for indicating a vacuum pump located under a vacuum vessel of the processing unit shown in FIG. 2, which is located as a center, in an enlarged manner;

FIG. 4A is a plan view for schematically showing a construction of the vacuum pump indicated in FIG. 3;

FIG. 4B is a plan view of an entrance vane of the vacuum pump, as viewed from an upper direction;

FIG. 4C is a side view of the entrance vane of the vacuum pump, as viewed from a side direction;

FIG. 5 is a longitudinal sectional view for schematically representing a construction of a vacuum pump according to a modification of the present invention, which is different from the embodiment of the present invention shown in FIG. 2, or FIG. 3;

FIG. 6 is a longitudinal sectional view for schematically representing a construction of a vacuum pump according to another modification of the present invention, which is further different from the embodiment of the present invention shown in FIG. 2, or FIG. 3; and

FIG. 7 is a flow chart for describing operations of the plasma processing apparatus according to the embodiment of FIG. 1A and FIG. 1B.

### DETAILED DESCRIPTION OF THE EMBODIMENTS

Referring now to drawings, various embodiments of the present invention will be described in detail.

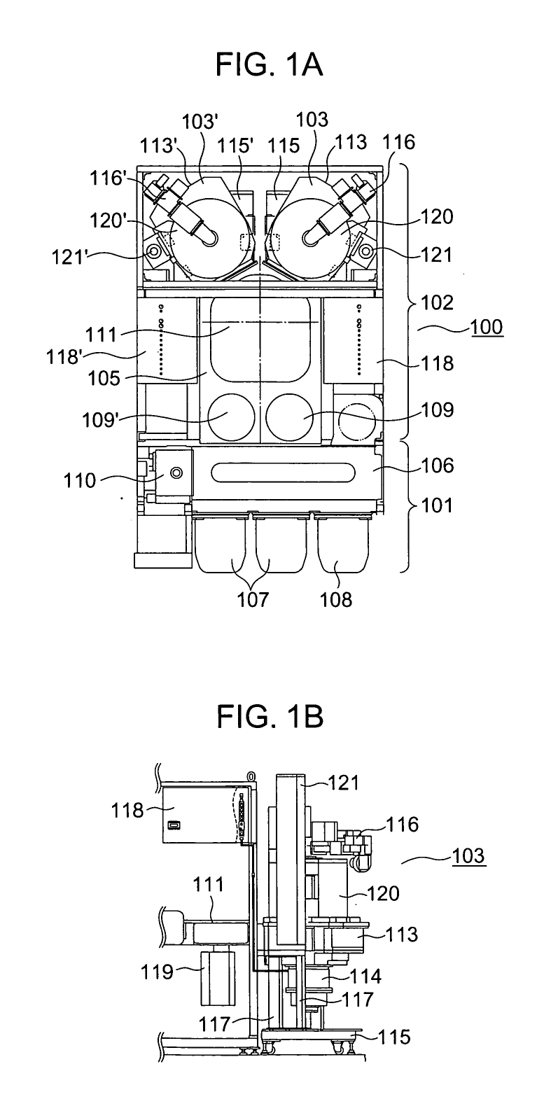

A plasma processing apparatus according to an embodiment of the present invention will now be explained with employment of FIG. 1A to FIG. 4C. FIG. 1A and FIG. 1B are diagrams for schematically showing constructions of a plasma processing apparatus 100 according to an embodiment of the present invention. FIG. 1A is a plan view for showing the plasma processing apparatus 100 according to the embodiment, as viewed from an upper direction. FIG. 1B is a side view for indicating a portion of the plasma processing apparatus 100 shown in FIG. 1A, more specifically, for showing a processing chamber and a portion of a vacuum pump for exhausting an inside of the processing chamber so as to reduce pressure, as viewed from a side direction. In the processing chamber, a vacuum vessel is located at a center thereof, and is used in order to process a sample having a board shape such as a semiconductor wafer by employing plasma produced within a space of the processing chamber which is vacuumized. In the portion, the vacuum pump is located at a center.

In these drawings, the plasma processing apparatus 100 according to the present embodiment is mainly subdivided into two blocks. A front side of a main body of the plasma processing apparatus 100 corresponds to an atmospheric-sided block 101. In the atmospheric-sided block 101, a wafer supplied to the plasma processing apparatus 100 is transported to a chamber whose pressure is decreased under atmospheric pressure and then is supplied to the processing chamber. A rear side of the main body of the plasma processing apparatus 100 corresponds to a processing block 102.

The atmospheric-sided block 101 contains a housing 106 which is equipped with a transport robot (not shown) therein. Both a wafer cassette 107 and a dummy wafer-purpose dummy cassette 108 are provided in the atmospheric-sided block 101, and are mounted on this housing 106. Either a processing-purpose wafer or a cleaning-purpose wafer has been stored in the wafer cassette 107. Furthermore, the transport robot performs to convey wafers into, or convey wafers out between these cassettes 107 and 108, and locking chambers 109 and 109′. Also, the atmospheric-sided block 101 is equipped with a positioning unit 110 over this housing 106. The positioning unit 110 positions wafers which are transported within this positioning unit 110, or positions wafers in fitted to attitudes of wafer arrangements within the locking chambers 109 and 109′.

The processing block 102 is provided with processing units 103 and 103′, a transporting unit 105, and a plurality of locking chambers 109 and 109′. In the processing units 103 and 103′, processing chambers where wafers are processed are arranged in a vacuum vessel, the internal pressure of which is reduced. The transporting unit 105 transports the wafers to these processing chambers under reduced pressure, and are constructed in the shape of a substantially polygon (substantially, pentagon in this embodiment) as viewed in a plane shape from the upper direction. The plural locking chambers 109 and 109′ connect the transporting unit 105 to the atmospheric-sided block 101. Pressure in these units is reduced, so that these units can maintain a high vacuum degree. The processing block 102 corresponds to a vacuum processing-purpose block.

Also, the processing units 103 and 103′ of the processing block 102 in the present embodiment are arranged in such a manner that these processing units 103 and 103′ are located parallel to two adjoining edges of the above-explained substantially pentagon of the transporting unit 105. In the present embodiment, these processing units 103 and 103′ correspond to etching processing units which are equipped with such a processing chamber that an etching process operation is carried out with respect to a wafer transported from the cassette 107 to the processing block 102. The transporting unit 105 is equipped with a vacuum transporting chamber 111 to which these processing units are detachably mounted, and which corresponds to such a space that pressure of an internal chamber is reduced to a high vacuum degree, and to which a wafer is transported by maintaining the high vacuum degree.

Also, the plurality of locking chambers 109 and 109′ are connected to a vacuum exhausting apparatus (not shown) so as to own spaces which have been constructed capable of maintaining pressure under high vacuum condition and under atmospheric pressure condition in such a status that a semiconductor wafer to be processed is mounted within the respective internal portions. These locking chambers 109 and 109′ are opened/closed between either the atmospheric-sided block 101 or the housing 106 and the vacuum transporting chamber 111 in a communicatable manner by way of gate valves (not shown) which as arranged at front/rear edge portions, as viewed in the drawing. In the present embodiment, these locking chambers 109 and 109′ own equivalent functions to each other. These locking chambers 109 and 109′ are not directed to perform any one of pressure changing operations from vacuum to the atmospheric pressure, and from the atmospheric pressure to vacuum. However, any one of these pressure locking operations may be limited to be used based upon the required specification.

Furthermore, in this processing block 102, the above-explained respective processing units 103 and 103′ contain vacuum vessels 113 and 113′ having processing chambers, the internal pressure of which can be reduced and which perform etching operations. As will be explained later, exhausting means are arranged under these vacuum vessels 113 and 113′, while these exhausting means are employed so as to reduce internal pressure of processing chambers arranged therein. Furthermore, the respective processing units 103 and 103′ are fixed on a floor surface where the vacuum processing unit 100 is installed so as to be held by employing racks 115 and 115′, and a plurality of supporting pillars. The racks 115 and 115′ correspond to supporting bases which support the vacuum vessels 113 and 113′, and the exhausting member coupled to these vacuum vessels 113 and 113′ in the upper portions thereof. The supporting pillars are arranged above these racks 115 and 115′, and couple these racks 115, 115′ to the vacuum vessels 113, 113′ so as to support these vacuum vessels 113 and 113′.

In addition, coil cases 120 and 120′ are arranged above these vacuum vessels 113 and 113′. The coil cases 120 and 120′ have stored thereinto electromagnetic coils which apply magnetic fields so as to produce plasma in the processing chambers arranged therein. Furthermore, electromagnetic wave sources 116 and 116′ are arranged above the coil cases 120 and 120′. The electromagnetic wave sources 116 and 116′ contain power sources which are used to supply electric fields into the processing chambers, and waveguides which are tube paths into which the electric fields are conducted.

In order to maintain and check the electromagnetic wave source 116, or 116′, and the coil cases 120, or 120′, otherwise, in order to maintain and check the internal portions of the processing chambers by opening the vacuum processing chambers 113 and 113′ to the atmospheric space, these components must be moved along the upper direction. To this end, in the present embodiment, cranes 121 and 121′ such as a lifter and a jack are provided, while these cranes 121 and 121′ are mounted on the respective vacuum vessels 113 and 113′, and move both the electromagnetic wave source 116 and the coil case 120, or both electromagnetic wave source 116′ and the coil case 120′ along upper/lower directions. A user can easily perform the maintenance/checking works by opening the internal spaces of the vacuum vessels 113 and 113′ by operating these cranes 121 and 121′.

In the present embodiment, the cranes 121 and 121′ are provided on the processing units 103 and 103′ respectively, while the processing units 103 and 103′ are mounted on the respective side wall surfaces of the respective edges of the polygon of the vacuum transport chamber 111, the surface shape of which is a substantially polygon. These cranes 121 and 121′ are mounted on the side surfaces of the respective vacuum vessels 113 and 113′. The side surface thereof is mounted on a side surface of a vacuum vessel which is located opposite to the side of the adjacent vacuum vessel.

FIG. 1B indicates the processing unit 103 of the processing block 102 shown in FIG. 1A in an enlarged manner. As represented in this drawing, there is a space between the vacuum vessel 113 and the rack 115 for supporting this vacuum vessel 113 under the vacuum vessel 113. In these spaces, utility storing spaces are arranged so as to store the respective units, or apparatus which are required in processing operations within the processing chambers, and power sources for supplying electric power to these apparatus. Also, a plurality of supporting pillars 117 are arranged between the lower portion of the vacuum vessel 113 and the upper surface of the rack 115, and couple the vacuum vessel 113 to the rack 115 so as to support the vacuum vessel 113 and the coil case 120 positioned above the vacuum vessel 113. A vacuum pump 114 corresponding to the above-explained exhausting apparatus is arranged in this space by being coupled to the lower surface of the vacuum vessel 113.

The processing chamber corresponds to such a space which is used to process a sample to be processed and arranged inside this processing chamber 113 by employing produced plasma under pressure reduced condition. The processing chamber is communicated to the vacuum transporting chamber 111 via a passage (not shown). The vacuum transporting chamber 111 corresponds to such a space into which the sample is transported, and the pressure of which is reduced. This passage is closed, or opened by that the passage can be sealed by at least one gate valve (not shown).

Moreover, in the present embodiment, a mass flow controller 118 is provided within the processing chamber of the vacuum vessel 113. The mass flow controller 118 corresponds to a flow rate adjuster which adjusts a supply of gas for processing a sample. This mass flow controller 118 is also arranged on the side of the processing unit 103′, and is positioned at upper portions of both sides of the transporting unit 105. Plural sorts of gas are supplied from gas sources arranged under the floor surface (not shown) to this mass flow controller 118, and the flow rates of which gas are adjusted, and then, the resultant gas is supplied to the processing chamber within the processing unit 103. Also, a vacuum degree within the vacuum transporting chamber 111 is also maintained in such a vacuum degree which is nearly equal, or is slightly higher than the vacuum degree within the processing chamber. As a result, an exhausting apparatus 119 communicated to the vacuum processing chamber 111 is arranged under the transporting unit 105, so that the internal pressure of the vacuum transporting chamber 111 is adjusted to be predetermined pressure by operating the exhausting apparatus 119.

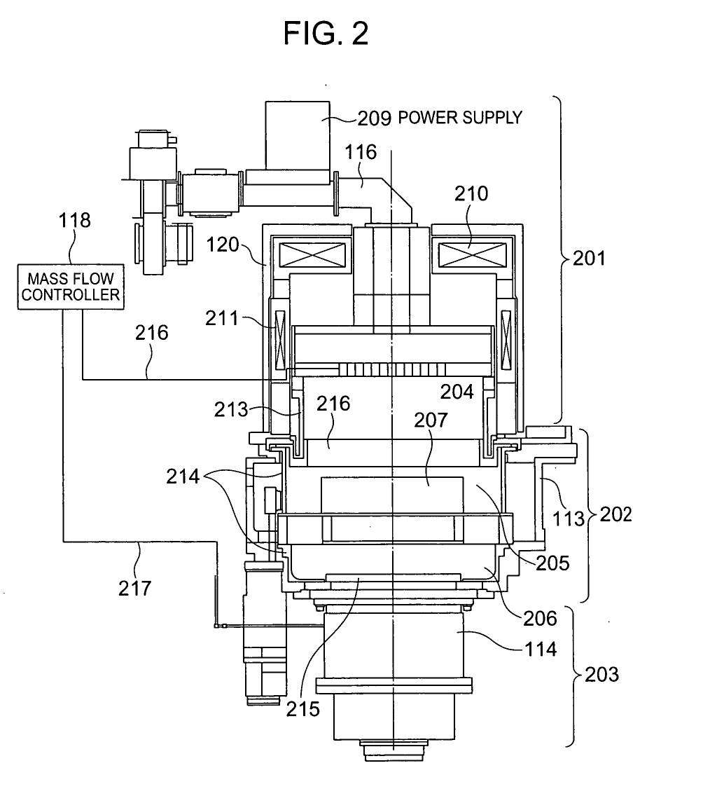

FIG. 2 is a sectional view for schematically representing constructions of the processing units 113 and 113′ shown in FIG. 1A and FIG. 1B. The processing unit 113 of the present embodiment is equipped with a discharging block 201; a vacuum block 201 which is coupled to a lower portion of the discharging block 201; and an exhausting block 203 which contains the vacuum pump 114 in this order from the upper direction thereof. The exhausting block 203 is provided under the vacuum block 202, and exhausts gas, plasma, particles of produced matters and the like, which are present in the processing chamber from the lower portion of the vacuum vessel 113. In this structure, process gas whose supply amount has been adjusted by the mass flow controller 118 is supplied to the discharging block 201, plasma is produced by using the electric field, or the magnetic field, which is applied from the electric field applying means, or the magnetic field applying means, and then, the sample arranged in the processing chamber is processed.

The above-explained process gas and plasma are downwardly moved within the vacuum block 202 in combination with the produced matters, which are produced in connection with this process operation. Furthermore, the gas and the particles within the vacuum block 202 are exhausted from the inside of the exhausting block 203 coupled to the vacuum block 202 by operating the vacuum pump 114.

In the present embodiment, the processing chamber arranged in the vacuum vessel 113, and a sample base 207 corresponding to a lower electrode arranged under this processing chamber are arranged in a substantially coaxial manner. Also, a lower electrode within the vacuum vessel is also arranged in a substantially coaxial manner with respect to the above-explained axis. Also, the vacuum pump 114 is arranged under the vacuum vessel 113 in a coaxial manner with respect to the lower electrode 207, and is arranged by defining a predetermined space with respect to the lower surface of the lower electrode 207 just under this lower electrode 207.

A space located above the lower electrode 207 of the discharging block 201 corresponds to a discharging chamber 204, and constitutes such a space into which the process gas is supplied from the mass flow controller 118, and in which plasma is formed above the sample. The particles contained in the plasma formed in the discharging chamber 204, the particles of the produced matters, and the process gas are exhausted through a vacuum vessel 205 and another vacuum vessel 206 outside the vacuum vessel 113. The vacuum vessel 205 corresponds to a space located around the lower electrode 207 under the discharging chamber 204, and is surrounded by the vacuum vessel 113. The vacuum vessel 206 corresponds to such a lower space which is surrounded by the vacuum vessel 113 communicated with the above-explained vacuum vessel 205, and also corresponds to such a space defined between the lower surface of the lower electrode 207 and the vacuum pump 114.

In the present embodiment, a processing chamber is formed by the above-explained discharging chamber 204, and the vacuum vessels 205 and 206 contained in the vacuum block 202. In this processing chamber, a ceiling portion in the discharging chamber 204 located above is constructed of a shower plate 212, and a side peripheral portion is surrounded by a cylindrical inner wall 213 having a substantially cylindrical shape. A plurality of through holes are formed in the shower plate 212, through which the process gas are supplied. Also, a peripheral portion of the lower electrode 207 of the vacuum vessel 205 of the vacuum block 202 is constituted by an upper inside wall 214, and inside walls located below the vacuum vessel 206 and the lower electrode 207 are constituted by a lower inside wall 215 and an open/close lid 215 having a substantially circular shape. It should be understood that this open/close lid 215 is constituted by a disk having a diameter which is substantially equal to a diameter of the lower electrode 217 having the substantially cylindrical shape. The position of the open/close lid 215 can be changed along the upper/lower directions by a driving apparatus (not shown), and is moved up to a position just below the lower electrode 207 to be entered into a projection surface of the lower electrode 207, as viewed from the upper direction, and is covered by this projection surface so that the particles or gasses can flow out of the processing chamber. Also, the open/close lid 215 is moved to the lower portion, so that the open/close lid 215 can seal a space between the vacuum vessel 206 and an entrance of the vacuum vessel 114 so as to block this space.

In the above-explained construction, in the processing unit 103 of the present embodiment, a sample is mounted on the mounting surface over the lower electrode 207, and thereafter, process gas is conducted from the upper portion into the discharging chamber 204 via the through holes formed in the shower plate 212. The positions of the through holes have been arranged within such a range having the same, or larger diameter as the diameter of the sample having the circular board shape located under these through holes.

Microwaves generated from a power supply 209 which constitutes the electromagnetic wave source 116 are penetrated via the waveguide 208 through the shower plate 212, and then, are conducted into the discharging chamber 204. Furthermore, solenoid coils 210 and 211 are arranged at positions which are surrounded by the external coil cases 120 located upwardly and sidewardly with respect to the discharging chamber 204. These solenoid coils 210 and 211 apply magnetic fields within the discharging chamber 204. The process gas contained in the discharging chamber 204 is energized due to mutual action between these electric field and magnetic field, so that plasma is formed, and furthermore, under such a condition that predetermined high frequency electric power is supplied to an electric conducting member arranged in the lower electrode 207, so that a bias potential is formed on the surface of the sample, a process operation as to the sample is carried out. Moreover, while the process operation of the sample is carried out, the gas and the particles contained in the processing chamber are moved along the lower direction of the processing chamber by way of the exhausting operation by the vacuum pump 114 under the vacuum vessel 206, and flows having small deviation are produced around the axis of the lower electrode 207 which is positioned at a center, so that the pressure within the chamber is adjusted to predetermined pressure.

In addition, in the present embodiment, means for adjusting an exhausting amount by the vacuum pump 114 is arranged outside the passage for passing the gas and the particles exhausted from the processing chamber. In other words, as shown in FIG. 2, a conducting passage 217 is provided which is arranged parallel to the conducting passage 216 for the process gas which is supplied to the discharging chamber 204. The predetermined gas is conducted via this conducting passage 217 to the vacuum pump 114. Although the flow rates of the predetermined gas supplied to the vacuum pump 114 are adjusted by the mass flow controller 118 which adjusts the flow rates of the process gas supplied to the discharging chamber 204 in the present embodiment, flow rate adjusting apparatus which are different from each other may be alternatively provided.

In the present embodiment, as the predetermined gas, either inert gas such as argon gas or nitrogen gas is employed which may give a small influence to the members which constitute the exhaust gas passage, or a small influence to the process operation within the processing chamber. Since the inert gas whose flow rate has been adjusted is conducted to a compressing unit of the vacuum pump 114, and the essential exhausting amount of the gas within the processing chamber per unit time is adjusted by the vacuum pump 114, the plasma processing apparatus of the present embodiment is so arranged by that the pressure within the processing chamber may be adjusted.

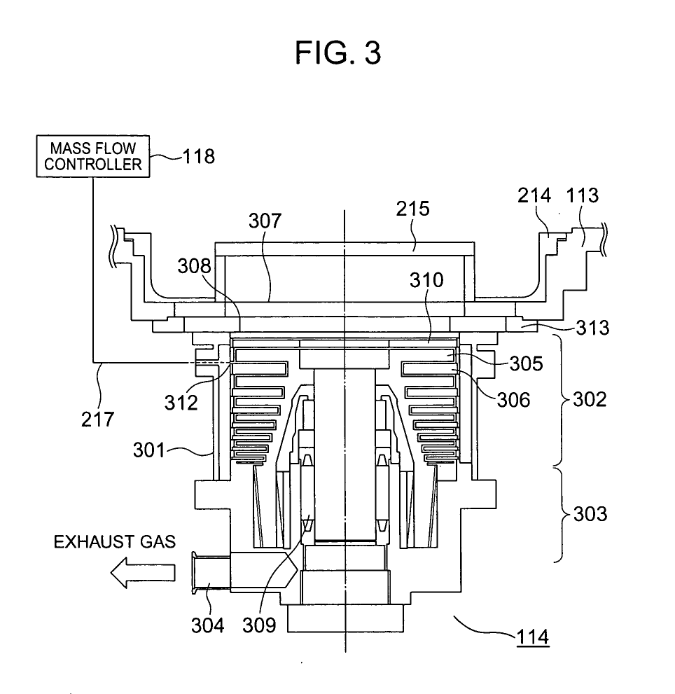

FIG. 3 is a longitudinal view for showing the vacuum pump 114 located under the vacuum vessel 113 of the processing unit 103 shown in FIG. 2 in an enlarged manner, while the vacuum pump 114 is located at a center. In this drawing, the vacuum pump 114 of the present embodiment has been fastened to the vacuum vessel 113 by employing a bolt, and the like via a coupling flange 313 mounted on the lower surface of the vacuum vessel 113.

The main body of the vacuum pump 114 is equipped with a compressing unit which is rotated within the case 301 having the substantially cylindrical shape so as to compress the gas, and a driving unit for rotating a rotation axis arranged at a center of the compressing unit, and also is equipped with an exhausting port 304 which exhausts the gas within the processing chamber, while the gas is compressed downwardly and the pressure thereof is increased. The upper portion within the case 301 constitutes a turbo-unit 302. The turbo-unit 302 is provided with respect stages of rotary vanes 305, and plural stages of fixed vanes 306. In the rotary vanes 305, a plurality of impeller blades are arranged in a radial form around the rotation axis. The fixed vanes 306 are equipped with a plurality of impeller blades which are arranged among these rotary vanes 305 and are elongated from the outer peripheral side of the case 301 to the rotation axis side in the radial form, while these fixed vanes 306 are coupled to the case 301 so as to fix the positions thereof. In addition, a screw unit 303 is arranged on the lower side of this turbo-unit 302, and is coupled to an exit of the turbo-unit 302. The gas exhausted from the turbo-unit 302 is entered into the screw unit 303. In the screw unit 303, a screw is formed in a portion which is coupled to the case 301 so as to fix the position thereof, and another screw is formed in a portion which is arranged opposite to the first-mentioned portion via a small gap and is rotated around the rotation axis, and thus, gas passes through the passage between these screw portions so as to be exhausted.

While a space provided on the rear edge of the screw unit 303 is communicated with the exhaust port 304, the gas which passes through the turbo-unit 302 and the screw point 303 whose pressure is increased is exhausted via the space. With employment of the above-explained structure, the gas and the particles within the processing chamber, which have been entered from the exhausting port 7 which is opened/closed by the open/close lid 215 and is formed in the lower portion of the vacuum vessel 113, are entered from an intake port 308 of the exhausting pump 114 into the turbo-unit 302 of the compressing unit. The intake port 308 is communicated to the exhaust port 307, which is located under this exhaust port 307. In the turbo-unit 302, the gas and the particles are fed out downwardly due to mutual actions produced among the vanes of the respective stages, which are relatively moved opposite to each other around the rotation axis. While the gas and the particles are penetrated through the spaces between the rotary vanes 304 and the fixed vanes 306 to be fed out downwardly, these gas and particles are compressed. The gas and particles exhausted from the turbo-unit 302 are penetrated through the lower screw unit 303 to be moved to the downstream side, and then, are exhausted from the exhaust port 304 in predetermined pressure.

Either the rotary vanes 305 or the rotary portions of the screw unit 303 are coupled via a rotation shaft to a motor unit 309, and these rotary vanes 305 and the rotary portions are rotated by driving the motor unit 309 so as to exhaust in the processing chamber. It should be noted in order to smoothly rotate this rotation shaft, a magnetic bearing is arranged under the lower edge portion of the rotation shaft. Also, the intake port 308 of this vacuum pump 114 is directly communicated with the exhaust port 307, so that these members are arranged in such a manner that the intake port 308 may be directly observed from the inside of the processing chamber.

More specifically, in this embodiment, an entrance vane 310 at the uppermost stage of the turbo-unit 302, namely at a stage which is observed to the intake port 308 corresponds to such a vane whose position is fixed on the side of the case 301. The entrance vane 310 being one of the fixed vanes 306 is positioned at the uppermost stage of the compressing unit and is communicated to the exhaust port 307 and the processing chamber via a space under the open/close lid 215. The shapes of the respective impeller blades of the entrance vane 310 of the present embodiment are equivalent to the fixed vanes of other stages of the turbo-unit 302, while the plurality of impeller blades are elongated from the center of the rotation axis toward a ring-shaped outer circumference in a radial shape. This entrance vane 310 is not coupled to the rotary vane 305 of the uppermost stage of the lower turbo-unit 302, and thus, is constructed in such a manner that this entrance vane 310 can be dismounted, and mounted along the internal direction of the processing chamber.

A conducting port 312 is arranged between the rotary vane 305 of the uppermost stage of the turbo-unit 302 of the vacuum pump 114 and the impeller blade of the fixed vane 306 which is located just under this rotary vane 305. Into the conducting port 312, inert gas whose flow rate has been adjusted by the mass flow controller 118 is conducted via the gas conducting passage 217. This conducting port 312 is communicated with a conducting passage 217 mounted on the flange portion having the thicker thickness which is arranged by surrounding the outer circumference of the case 301, while the case 301 surrounds an outer circumferential edge of the rotary vanes having the substantially cylindrical shapes. A plurality of the above-explained conducting ports 312 are arranged on the rotation axis of the compressing unit in a substantially symmetrical shape. The inert gas conducted into the turbo-unit 302 is fed out to the downstream side in combination with the gas and the particles from the processing chamber by way of the exhausting operation of the turbo-unit 302, and then, are finally exhausted from the exhausting port 304.

While the amounts of the gas and the particles which are essentially exhausted from the processing chamber have been reduced by conducting the inert gas, since the conducting amount of this inert gas is adjusted, the exhausting amount from the processing chamber is adjusted, so that pressure in the discharging chamber 204, the vacuum vessels 205, and 206 may be adjusted. A flow rate of the inert gas from the conducting port 312 is adjusted by the mass flow controller 118 of this embodiment in response to a pressure difference between pressure on the side of the inert gas source and pressure on the side of the conducting port 312. Since the pressure on the side of the inert gas source has been set to such a pressure which has been preset based upon a housing such as a clean room where the plasma processing apparatus is installed, the pressure difference can be made large. Accordingly, the flow rate can be adjusted in high precision, and the precision in the processing operation can be improved.

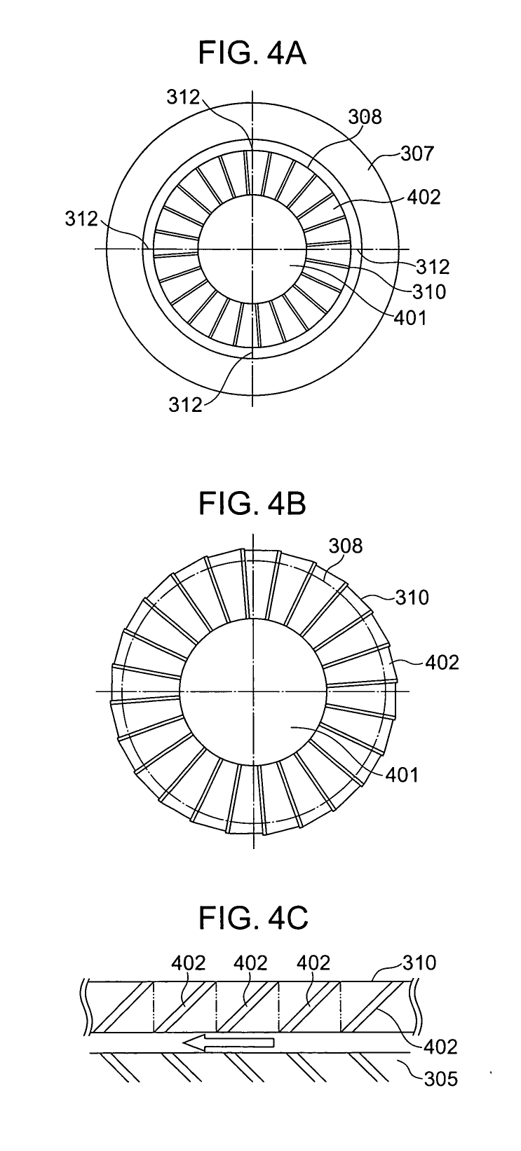

FIG. 4A to FIG. 4C are diagrams for schematically indicating constructions of the vacuum pump 114 shown in FIG. 3. FIG. 4A is a plan view for indicating the vacuum pump 114 which is observed from the processing chamber above the exhausting port 307. FIG. 4B is a plan view for indicating the entrance vane 310 of the vacuum pump 114 as viewed from the upper portion. In the present embodiment, while the sample is processed, the vacuum vessel 206 is communicated with the compressing unit located above the vacuum pump 114 via the exhausting port 307 and the intake port 308, and neither such a means, nor an apparatus for adjusting the exhausting amount (for example, valve employed in conventional technique) is not provided between the opening of the vacuum vessel and the opening of the vacuum pump. In other words, while the exhausting port 307 located under the processing chamber is communicated with the entrance vane 310 corresponding to the fixed vane of the uppermost end of the compressing unit, this entrance vane 310 is directly exposed to the space within the processing chamber.

Also, the entrance vane 310 has a plurality of impeller blades 402, and an outer circumferential edge of each of the impeller blades 402 is extended up to the outer side of the inner circumferential edge of the intake port 308. These plural impeller blades 402 are elongated in a radial shape on an outer circumferential side of a cover 401 having a substantially circular shape, which is arranged at a position corresponding to an upper portion of the rotation axis. Also, a plurality of gas conducting ports 312 are arranged at a plurality of places (4 places in this embodiment) in an axial symmetrical manner around the center of the rotation axis of the rotary vane 305 located at a center of this drawing, so that these gas conducting ports 312 can suppress that an ununiform condition of the exhausting operation along the inner surface direction occurs due to the conducted gas.

Further, in the entrance vane 310 corresponding to the fixed vane of the first stage of the turbo-unit 302, as shown in FIG. 4B, a plurality of vanes 402 are arranged without forming any gap among these vanes 402, as viewed from the upper direction. The plural vanes 402 are arranged in a radial form along the rotation axial direction of the center portion thereof from the case having the substantially cylindrical shape of the vacuum pump 114. FIG. 4C is a side view of the entrance vane 310, as viewed from the side direction, and is a diagram for schematically representing an arrangement of the respective impeller blades. As shown in this drawing, the respective impeller blades are arranged in such a manner that predetermined gaps are opened along a direction perpendicular (horizontal direction) to the rotation axis which corresponds to the upper/lower direction on this drawing, and angles are formed as to the rotation direction of the rotary vane 305 and the rotation axis, while the rotary vane 305 is arranged along an immediately lower direction indicated by an arrow on this drawing. Each of the impeller vanes owns an upper upstream end and a lower downstream and with respect to either the rotation axis or the exhaust gas flow direction. The upstream end is arranged upwardly and the downstream end is arranged downwardly as to the rotation direction of the rotary vane 305 located along the just below direction. This is directed opposite to the mounting angle of each of the impeller blades of the rotary vane 305. In the case that the entrance vane 310 is observed from the upper direction of the rotation axis, the upstream end of each of the impeller blades is overlapped with the downstream end of the adjacent impeller blade. As a consequence, the turbo-unit 302 located under the entrance vane 310 is not exposed in the case that the turbo-unit 302 is projected from the upper portion of the vacuum pump 114. With employment of this construction, it is possible to suppress that contaminating materials present in the turbo-unit 302 are penetrated into the processing chamber in conjunction with the rotations of the turbo-unit 302 having the rotary vanes 305.

Also, the entrance vane 310 is detachably mounted on the inner side (upper side) of the processing chamber as a single body from the main body of the vacuum pump 114 from the inside of the case 301 of the vacuum pump 114, and also, under such a condition that the entrance vane 310 is mounted on the entrance of the vacuum pump 114, this entrance vane 310 is heated by way of a thermal conduction by a heater (heating unit, not shown) which is built in the vacuum pump 114. Since the entrance vane 310 is heated, it is possible to suppress that substances having strong adhesive characteristics, such as produced matters, from the processing chamber are adhered to the surface of the entrance vane 310. As a result, it is possible to suppress that these adhesive substance may give an adverse influence to the processing operation executed in the processing chamber, while these adhesive substances become contaminating materials. Also, even if such produced matters are adhered to the entrance vane 310, when the vacuum pump 114 is opened in order to maintain/check the processing chamber, the entrance vane 310 may be replaced without replacing the vacuum pump 114, and the replacing work can be readily carried out.

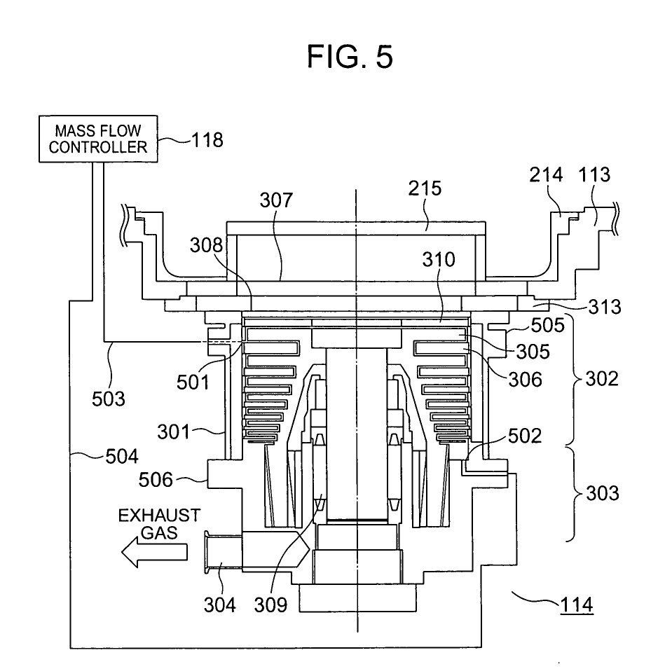

FIG. 5 is a longitudinal sectional view for schematically showing a construction of a vacuum pump according to a modification which is different from the embodiment of the present invention indicated in FIG. 2, or FIG. 3. A different point of this modification from the embodiment shown in FIG. 2, or FIG. 3 is given as follows: That is, a plurality of conducting ports for supplying gas are provided on both an upstream side and a downstream side of the compressing unit of the vacuum pump 114.

In other words, similar to the embodiment indicated in FIG. 2, or FIG. 3, in the modification shown in FIG. 5, a conducting port 501 is arranged on a side wall which is faced to the interval between the uppermost stage of the rotary vane 305 of the turbo-unit 302 and the fixed vane 306 located just under this rotary vane 305. Into the conducting port 501, such an inert gas is conducted, the flow rate of which has been adjusted by the mass flow controller 118. This conducting port 501 is communicated to a gas conducting passage 503 which is mounted on a flange unit 505 which is formed on the outer peripheral portion of the case 301, and a thickness of a sectional plane thereof is made thick.

Moreover, in this modification, another gas conducting port 502 which is separately provided from the above-described conducting port 501 and into which inert gas is conducted is arranged to be faced to the flow passage of the exhaust gas between the downstream end (exhausting end) of the turbo-unit 302 and the entrance of the screw portion 302. This gas conducting port 502 is communicated with another gas conducting passage 504. The gas conducting passage 504 is mounted under the case 301 on another flange portion 506 which is arranged under the above-explained flange portion 505.

In the present modification, a flow rate of inert gas which flows through the conducting passage 504 is also adjusted by the means flow controller 118 similar to the case of the conducting passage 503. On the other hand, the supply of the inert gas from the conducting port 502 via the conducting passage 504 may be alternatively adjusted by a flow rate adjusting apparatus which is different from the mass flow controller 118.

The gas which is supplied from the conducting port 501 to the upper turbo-unit 302 may be realized by inert gas and/or process gas, and this gas is conducted in order that the exhaust amount of the gas and the particles within the processing chamber by the vacuum pump 114 is largely varied. Also, the gas which is supplied to the lower conducting port 502 corresponds to inert gas, and this inert gas is conducted in order that the exhaust amount of the gas and the particles within the processing chamber by the vacuum pump 114 is varied in a relatively small amount. The pressure of the gas within the processing chamber, which is conducted from the upstream-sided conducting port 501 of the compressing unit of the vacuum pump 114 is largely varied by the gas conducted from the downstream-sided conducting port 502 whose pressure is high. On the other hand, in such a case that the pressure is varied in a small value, this pressure variation is realized by adjusting the conduction of the inert gas from the downstream-sided conducting port 502. Alternatively, the conducting port 502 may be formed in the screw unit 303.

For instance, if plural different sorts of films formed on a surface of a sample in a stacked layer are processed under different pressure values, in such a case that the pressure value is largely changed when a process operation of the lower film is carried out after the upper film is processed, since gas is supplied from the upstream-sided conducting port 501, the pressure within the processing chamber is largely varied in a shorter time duration, and a fine adjustment in order to stabilize the pressure within the processing chamber at predetermined pressure is carried out by conducting gas from the downstream-sided conducting port 502. With employment of this construction, the pressure within the processing chamber can be quickly changed and adjusted in response to the processing operations as to the different sorts of films, so that the efficiency of the processing operation can be improved.

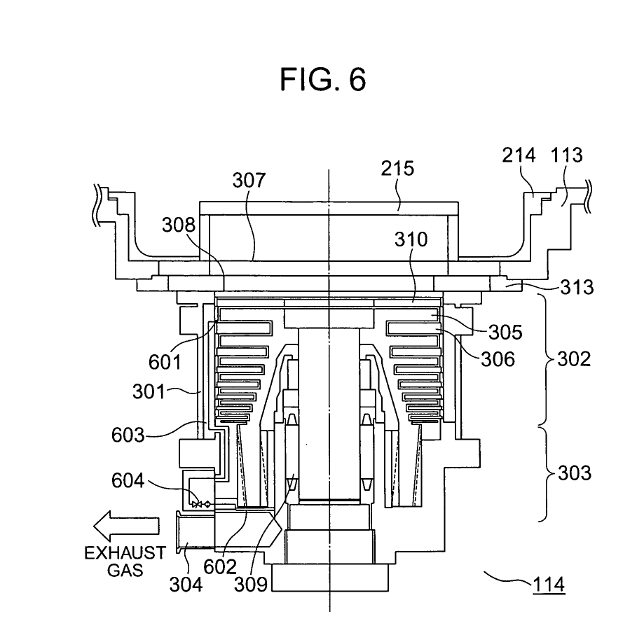

FIG. 6 is a longitudinal sectional view for schematically showing a construction of a vacuum pump according to a further modification which is different from the embodiment of the present invention indicated in FIG. 2, or FIG. 3. A different point of this modification from the embodiment shown in FIG. 2, or FIG. 3 is given as follows: That is, a conducting port 601 for supplying a portion of gas derived from the post flow end (exhaust end) of the screw unit 303 is provided in the turbo-unit 302 of the vacuum pump 114.

In other words, the present modification is not so arranged that the inert gas is conducted to the turbo-unit 302 of the vacuum pump 114, but is arranged as follows: A portion of exhaust gas on the post flow side of the compressing unit of the vacuum pump 114 is conducted to the turbo-unit 302 from a space between the rotary vane 305 of the uppermost stage and the fixed vane 306 located just under the rotary vane 305. The conducting port 601 is coupled via a return gas-purpose passage 603 to a return gas-purpose intake port 602 which is communicated with the exhaust end of the screw unit 303 and is opened. A flow rate adjuster 604 is arranged on the return gas-purpose passage 603, while this flow rate adjuster 604 is equipped with a check valve and either a flow rate adjusting nozzle or a flow rate adjusting valve in order to adjust a flow rate of the return gas.

An amount of exhaust gas of the vacuum pump 114 in the present modification is adjusted by the above-explained flow rate adjuster 604. As explained in this modification, even if the exhaust gas from the compressing unit of the vacuum pump 114 is returned to the entrance side of the compressing unit, then the pressure within the processing chamber may be adjusted by adjusting the amount of the exhaust gas by the vacuum pump 114. Also, in this modification, while the entrance vane 310 shown in FIG. 4 is arranged above the turbo-unit 302 of the vacuum pump 114, such a flow rate adjusting means as a valve is not arranged between the intake port 308 and the exhausting port 307 located under the vacuum vessel 113, but the exhaust gas from the processing chamber within the vacuum vessel 113 is directly supplied from the intake port 308 of the vacuum pump 114 to the entrance vane 310.

In accordance with this modification, it is possible to suppress that substances which become contaminating materials among the components contained in the exhaust gas returned to the turbo-unit are penetrated into the vacuum vessel, so that the pressure within the vacuum vessel can be made stable and the process operation can be carried out under stable condition.

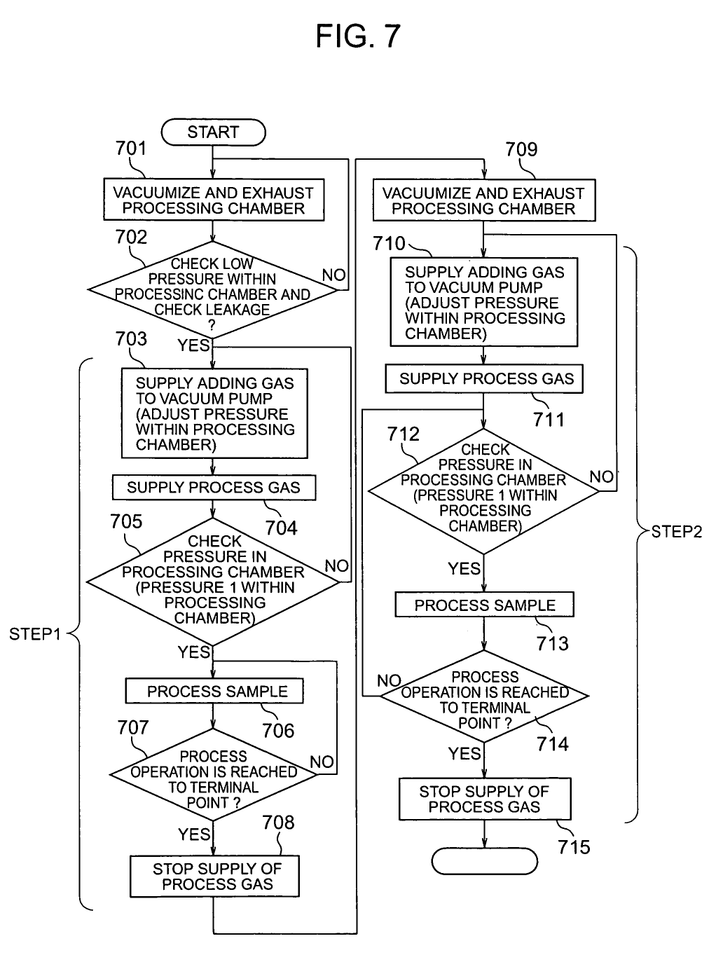

FIG. 7 is a flow chart for describing flow operations as to the plasma processing apparatus 100 according to the above-explained embodiment of FIG. 1. This flow chart indicates pressure adjusting operation within the processing chamber and process flow operations in the case that a plurality of film layers arranged on a surface of a sample in a stacked layer are processed under conditions different from each other.

In this drawing, in order to realize a condition for processing an upper film, first of all, the vacuum pump 114 is rotated so as to start an exhausting operation within the processing chamber when the process operation of the sample is commenced (step 701), and a confirmation is made as to whether or not pressure within the processing chamber is reached to predetermined pressure, and also whether or not a leakage occurs (step 702). Subsequently, after the sample is transported by such a transporting apparatus as a robot arm (not shown) and then is mounted on the lower electrode 207, such a gas which is used to dilute the process gas is conducted from the shower plate 212 located above the discharging chamber 204. In this case, the conductions of the above-explained gases are adjusted by the mass flow controller 118.

In connection with the above-explained process operation, while a flow rate of inert gas is adjusted by the mass flow controller 118 and the adjusted inert gas is supplied to the conducting port 312 of the vacuum pump 114, an amount of exhaust gas within the processing chamber is adjusted by the vacuum pump 114 and the adjustment is commenced in order that the pressure within the processing chamber is approximated to a predetermined pressure value, and then, a process operation of STEP 1 is started (step 703). Thereafter, the process gas is supplied from the shower plate 212 by adjusting the flow rate thereof by the mass flow controller 118 (step 704), and then, a confirmation is made as to whether or not the pressure within the processing chamber has been set to a predetermined pressure value (step 705).

In the case that the judgement is made that the pressure is not reached to the predetermined value, the process operation is returned to the step 703 in which the flow rate of the inert gas is adjusted by the mass flow controller 118. Also, when it is so judged that the pressure is reached to such a range which is sufficiently approximated to the predetermined value, the process operation is advanced to a step 706 in which process operation of the sample is commenced (step 706).

After the process operation has been commenced, a judgement is made as to whether or not the process operation is reached to an end point (step 707). When it is so judged that the process operation is not yet reached to the end point, the process operation is returned to the previous step 705 in which the process operation is continued while the pressure within the processing chamber is adjusted. On the other hand, when it is so judged that the process operation is reached to the end point, the supply of the process gas is stopped by the mass flow controller 118 (step 708).

Next, the respective conditions corresponding to process operations for a lower film are changed to be set. To this end, similar to the step 701, the inside of the processing chamber is vacuum-exhausted by operating the vacuum pump 114 so as to exhaust the respective process gases and produced matters which are employed in STEP 1. When the pressure within the processing chamber is exhausted up to a predetermined pressure value and it is so confirmed that the exhausting operations of these gases and produced matters are accomplished, inert gas is supplied to the conducting port 312 of the vacuum pump 114 while the flow rate of this inert gas is adjusted by the mass flow controller 118, and also, the amount of the exhausted gas within the processing chamber is adjusted by the vacuum pump 114, and thus, such an adjusting operation is started in order that the pressure within the processing chamber is approximated to a predetermined pressure value, and a process operation of STEP 2 is commenced (step 710). In this case, a conduction amount of the inert gas becomes different from the conduction amount of the step 703 if the pressure conditions within the processing chamber are different from each other in STEP 1 and STEP 2.

Furthermore, such a process gas whose flow rate and composition correspond to those of the process operation STEP 2 is conducted from the shower plate 212 into the processing chamber containing the discharging chamber 204 (step 711), and then, a confirmation is made as to whether or not the pressure within the processing chamber becomes a proper pressure value for the processing operation of STEP 2 (step 712). When it is so judged that the pressure dose not become the proper pressure value, the process operation is returned to the step 710. To the contrary, when it is so judged that the pressure becomes the proper pressure value, the process operation is advanced to a step 713 in which the process operation for the lower film is commenced (step 713).

Also, in this case, similar to the step 706, predetermined high frequency electric power is applied to the lower electrode 207 to form a bias potential on the surface of the sample so as to perform the process operation. Also, the process operation is carried out, while a temperature of a coolant is adjusted which is penetrated through a coolant passage within the lower electrode 207 during process operation, or while pressure of gas having a heat transfer characteristic (e.g., helium gas) is adjusted which is supplied between the sample and the sample mounting surface of the lower electrode 207.

After the process operation has been commenced, a judgement is made as to whether or not the process operation is reached to an end point (step 714). When it is so judged that the process operation is not yet reached to the end point, the process operation is returned to the previous step 712 in which the process operation is continued while the pressure within the processing chamber is adjusted. On the other hand, when it is so judged that the process operation is reached to the end point, the process operation is advanced to a step 715 in which the process gas to the processing chamber is stopped, and the process operation is stopped. Subsequently, in the case that there is a film which should be furthermore processed, the above-explained steps are repeated.

In the present embodiment, the adjusting operation of the pressure within the processing chamber in either the step 703 or the step 710 is carried out by adjusting the amount of the exhaust gas from the processing chamber by conducting the gas into the compressing unit of the vacuum pump 114 which is rotated. Alternatively, in order to more quickly change the pressure within the processing chamber from STEP 1 to STEP 2, the process operation may be advanced to the step 710 without executing the step 709 in which the process gas for STEP 1 is once exhausted from the processing chamber.

In the example shown in FIG. 7, the construction of the vacuum pump 114 has been explained under such an initial condition that the vacuum pump construction of FIG. 2, or FIG. 3 is employed. Alternatively, the construction of the vacuum pump 114 shown in FIG. 6 may be applied to the example of FIG. 7. Also, while the conducting ports 501 and 502 for supplying the inert gas may be arranged at a plurality of places on both the upper stream side and the lower stream side of the compressing unit as shown in FIG. 5, in such a case that the pressure within the processing chamber is largely varied in the step 710, the inert gas may be firstly and alternatively conducted from the conducting port 501 so as to largely very the exhausting amount by the vacuum pump 114, so that the exhausting amount is approached to a target exhausting amount (target pressure). Thereafter, the present conduction of this inert gas may be switched to a conduction of the inert gas from the conducting port 502, and an exhausting amount may be alternatively adjusted in a fine mode in order that the exhausting amount may become the target pressure.

As previously described, in accordance with the above-described embodiments, the pressure in the processing chamber can become more stable, and the efficiency of the processing operation can be improved. Also, it is possible to suppress that the contaminating materials are penetrated from the vacuum pump to the processing chamber, so that the processing yield can be improved. Also, the time required for the maintenance and checking operation can be shortened, so that the operability of the plasma processing apparatus can be improved.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus for processing a sample by employing plasma produced in a processing chamber, comprising:
a processing chamber in which plasma is formed while process gas is supplied to an inner portion thereof;
a sample base in which a sample to be processed is mounted on an upper surface of said sample base;
a vacuum pump for exhausting gas within the processing chamber from a lower portion of the sample so as to reduce pressure within the processing chamber, said vacuum pump being equipped with a compressing unit having a rotary vane and a fixed vane arranged within a case of said vacuum pump, and an exhausting port for exhausting said gas exhausted from said processing chamber outside said case of said vacuum pump; and said rotary vane and said fixed vane having a plurality of impeller blades arranged in a coaxial manner; and
a conducting port arranged between a rotary vane arranged at the uppermost position of said compressing unit and a fixed vane located under said rotary vane, into which inert gas is conducted; and
a flow rate adjusting device arranged between a gas storage unit of said inert gas and said conducting port, for adjusting an amount of said inert gas.

2. A plasma processing apparatus as claimed in claim 1 wherein:
said vacuum pump is comprised of: a turbo-unit having both said rotary vane and said fixed vane, which are arranged in an alternate manner, or an upper/lower direction; and the gas within said processing chamber is directly conducted into an entrance vane from an opening which is communicated to said vacuum vessel, said entrance vane is arranged at an entrance of said turbo-unit and owns the shape of said rotary vane.

3. A plasma processing apparatus as claimed in claim 1 wherein:
said vacuum pump is arranged under said vacuum vessel; and said vacuum pump is directly coupled to an entrance vane having the shape of said rotary vane, which is detachably arranged on an upper entrance portion of a turbo-unit which is mounted under an opening communicated to said processing chamber and is arranged by alternately overlapping said rotary vane with said fixed vane; and
said entrance vane is heated by a heating unit in order to avoid that contaminating materials are adhered to said entrance vane.

4. A plasma processing apparatus as claimed in claim 2 wherein:
said inert gas conducting port is provided between said rotary vane of a first stage and a fixed vane of a subsequent stage, and said inert gas is supplied from said inert gas conducting port.

5. A plasma processing apparatus as claimed in claim 3 wherein:
said gas returning port is arranged between said rotary vane of the first stage and said fixed vane of said subsequent stage.

6. A plasma processing apparatus for processing a sample by employing plasma produced in a processing chamber, comprising:
a processing chamber in which plasma is formed while process gas is supplied to an inner portion thereof;
a sample base in which a sample to be processed is mounted on an upper surface of said sample base; and
a vacuum pump equipped with a compressing unit, an exhausting port, a conducting port, a gas returning port, and a flow rate adjusting device, which exhausts gas within a processing chamber from a lower portion of the sample so as to reduce pressure; said compressing unit being constituted by both a rotary vane and a fixed vane which are made of a plurality of impeller blades in a coaxial manner arranged within a case of the vacuum pump under said processing chamber; said exhausting port exhausting said gas exhausted from said compressing unit outside said case; said conducting port being arranged on an outer circumference of said compressing unit between said rotary vane and the fixed vane located under said rotary vane, into which inert gas is conducted; said returning port being arranged on the exhaust side of said compressing unit, which supplies said exhausted gas to said conducting port; and also, said flow rate adjusting device being arranged on a passage for said gas between said gas returning port and said conducting port, which adjusts a flow rate of said gas.

7. A plasma processing apparatus as claimed in claim 6 wherein:
said vacuum pump is comprised of: a turbo-unit having both said rotary vane and said fixed vane, which are arranged in an alternate manner, or an upper/lower direction; and the gas within said processing chamber is directly conducted into an entrance vane from an opening which is communicated to said vacuum vessel, said entrance vane is arranged at an entrance of said turbo-unit and owns the shape of said rotary vane.

8. A plasma processing apparatus as claimed in claim 6 wherein:
said vacuum pump is arranged under said vacuum vessel; and said vacuum pump is directly coupled to an entrance vane having the shape of said rotary vane, which is detachably arranged on an upper entrance portion of a turbo-unit which is mounted under an opening communicated to said processing chamber and is arranged by alternately overlapping said rotary vane with said fixed vane; and
said entrance vane is heated by a heating unit in order to avoid that contaminating materials are adhered to said entrance vane.

9. A plasma processing apparatus as claimed in claim 7 wherein:
said inert gas conducting port is provided between said rotary vane of a first stage and a fixed vane of a subsequent stage, and said inert gas is supplied from said inert gas conducting port.

10. A plasma processing apparatus as claimed in claim 8 wherein:
said gas returning port is arranged between said rotary vane of the first stage and said fixed vane of said subsequent stage.
